(19) United States
(12) Patent Application Publication
(10) Pub. No.: US 2025/0046674 A1
(43) Pub. Date: Feb. 6, 2025

(54) Recess Island Lid Design for TIM Delamination Risk Mitigation

(71) Applicant: Apple Inc., Cupertino, CA (US)

(72) Inventors: Suk-Kyu Ryu, San Jose, CA (US); Wei Hu, Santa Clara, CA (US); Jie-Hua Zhao, Cupertino, CA (US); Myung Jin Yim, San Jose, CA (US)

(21) Appl. No.: 18/365,062

(22) Filed: Aug. 3, 2023

(51) Int. Cl. H01L 23/42; H01L 23/00; H01L 23/367

(52) U.S. Cl. CPC H01L 23/42; H01L 23/367; H01L 23/562; H01L 24/32; H01L 24/16; H01L 24/33; H01L 24/73; H01L 2224/16225; H01L 2224/32225; H01L 2224/32245; H01L 2224/33181; H01L 2224/73204; H01L 2224/73253

(57) ABSTRACT

A module comprising: a module substrate; a system-on-chip die coupled to the module substrate; a thermal interface material layer coupled to the system-on-chip die; a stiffener structure positioned around the system-on-chip die and coupled to the module substrate; and a lid having a first portion coupled to the thermal interface material layer, a second portion coupled to the stiffener structure and a recessed region formed around the first portion and having a reduced thickness relative to the first portion and the second portion.

### BACKGROUND

### Field

Embodiments described herein relate to multiple chip modules, and in particular to lids thereof.

### Background Information

Lids are widely used in multiple chip modules (MCMs) for a variety of reasons, such as to provide mechanical integrity, hermetic sealing from environment, and thermal performance. In an exemplary implementation one or more components are surface mounted onto a module substrate, and then optionally underfilled. A lid is then secured onto the module substrate and over the component(s).

### SUMMARY

Thermal Interface Material (TIM) plays a role in transferring heat between system-on-chip (SOC) die and metal lid structures. Thus, TIM integrity is very critical for efficient thermal management in the system. However, soft TIM material selection is very limited due to TIM delamination concern during reliability test conditions (e.g., thermal cycle, drop test or HTHH). Aspects described herein therefore relate to multiple chip module (MCM) structures in which the lid is configured to obtain the mechanical integrity and thermal benefits of a lid, and reduced warpage. In particular, the lid may be configured to mitigate stress and reduce warpage potentially caused by mismatch of the coefficient of thermal expansion (CTE) of the lid and the rest of the MCM. For example, the lid may include a recessed island configuration that can significantly mitigate TIM stress by, for example, increasing local TIM Bond-Line Thickness (BLT) at high stress. The recess location and area can further be optimized based on SOC die hot spot. The lid configuration may also enable a wider range of TIM material selection.

Representatively, in some aspects, a module is disclosed including a module substrate, a system-on-chip die coupled to the module substrate, a thermal interface material layer coupled to the system-on-chip die, a stiffener structure positioned around the system-on-chip die and coupled to the module substrate, and a lid having a first portion coupled to the thermal interface material layer, a second portion coupled to the stiffener structure and a recessed region formed around the first portion and having a reduced thickness relative to the first portion and the second portion. The lid may be a single integrally formed structure. The lid may be a recessed region formed entirely around the first portion. The recessed region may be aligned with a gap between the system-on-chip die and the stiffener structure. In some aspects, a gap between the system-on-chip die and the stiffener structure may have a first width (W1) and the recessed region comprises a second width (W2) that is greater than zero and equal to or less than the first width (W1). In some aspects, the recessed region includes a depth (D) that is greater than zero and less than a thickness (T) of the first portion and the second portion of the lid. In still further aspects, the first portion may include a polygonal shape. In some aspects, a thermal interface material layer includes a first thermal interface material arranged along a center of the first portion and a second thermal interface material arranged along a corner of the first portion. In still further aspects, the recessed region may be a first recessed region and a second recessed region is formed in at least one corner or along at least one side of the first portion. In some aspects, the thermal interface material layer may include a single thermal interface material having a first thickness and a second thickness, the second thickness is formed in the second recessed region and is greater than the first thickness.

In another aspect, a module may include a module substrate, a system-on-chip die coupled to the module substrate, a thermal interface material layer coupled to the system-on-chip die, a stiffener structure positioned around the system-on-chip die and coupled to the module substrate and a lid having a bottom side comprising a first portion coupled to the thermal interface material layer and a recessed region formed entirely around the first portion that is aligned with a gap between the system-on-chip die and the stiffener structure. In some aspects, the lid is a single inseparable structure formed of a metal material. The recessed region may be formed entirely around the first portion. In some aspects, the gap between the system-on-chip die and the stiffener structure may have a first width (W1) and the recessed region comprises a second width (W2) that is greater than zero and equal to or less than the first width (W1). In some aspects, the recessed region may include a depth (D) that is greater than zero and less than a thickness (T) of the first portion or the second portion of the lid. The first portion may have a rectangular or a square shape. In some aspects, the thermal interface material layer includes a first thermal interface material and a second thermal interface material having a different thermal conductivity than the first thermal interface material, and the first or the second thermal interface material is confined to at least one corner of the first portion. In some aspects, the recessed region is a first recessed region and a second recessed region is formed in each corner of the first portion. The thermal interface material layer may include a single thermal interface material having a greater thickness within the second recessed region formed in each corner of the first portion than a remainder of the first portion. In still further aspects, the thermal interface material layer may include a first thermal interface material layer coupled to a top side of the system-on-chip die and a second thermal interface material layer is coupled to a bottom side of the system-on-chip die to attach the system-on-chip die to the module substrate.

The above summary does not include an exhaustive list of all aspects of the present disclosure. It is contemplated that the disclosure includes all systems and methods that can be practiced from all suitable combinations of the various aspects summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

The aspects are illustrated by way of example and not by way of limitation in the figures of the accompanying drawings in which like references indicate similar elements. It should be noted that references to “an” or “one” aspect in this disclosure are not necessarily to the same aspect, and they mean at least one.

FIG. 1 is an exploded isometric view illustration of a multiple chip module including a lid and stiffener structure in accordance with an embodiment.

FIG. 2 is a bottom perspective view of the lid of FIG. 1 in accordance with an embodiment.

FIG. 3 is a schematic cross-sectional side view illustration of the lid and stiffener structure of FIG. 1 in accordance with an embodiment.

FIG. 4 is a magnified schematic cross-sectional side view illustration of the lid and stiffener structure of a portion of FIG. 3 in accordance with an embodiment.

FIG. 5 is a magnified schematic cross-sectional side view illustration of the lid and stiffener structure of a portion of FIG. 3 in accordance with an embodiment.

FIG. 6 is a magnified schematic cross-sectional side view illustration of the lid and stiffener structure of a portion of FIG. 3 in accordance with an embodiment.

FIG. 7 is a bottom plan view of the lid of the lid of FIG. 1 in accordance with an embodiment.

FIG. 8 is a bottom plan view of an alternative configuration of the lid of FIG. 1 in accordance with an embodiment.

FIG. 9 is a bottom plan view of the lid and a TIM layer of FIG. 8 in accordance with an embodiment.

FIG. 10 is a magnified schematic cross-sectional side view illustration of the lid and TIM layer of a portion of FIG. 9 in accordance with an embodiment.

FIG. 11 is a magnified bottom plan view illustration of the lid and TIM layer of a portion of FIG. 9 in accordance with an embodiment.

FIG. 12 is a magnified schematic cross-sectional side view illustration of an alternative lid structure in accordance with an embodiment.

### DETAILED DESCRIPTION

In this section we shall explain several preferred aspects of this disclosure with reference to the appended drawings. Whenever the shapes, relative positions and other aspects of the parts described are not clearly defined, the scope of the disclosure is not limited only to the parts shown, which are meant merely for the purpose of illustration. Also, while numerous details are set forth, it is understood that some aspects of the disclosure may be practiced without these details. In other instances, well-known structures and techniques have not been shown in detail so as not to obscure the understanding of this description. For example, in some instances, well-known semiconductor processes and manufacturing techniques have not been described in particular detail in order to not unnecessarily obscure the embodiments.

The terminology used herein is for the purpose of describing particular aspects only and is not intended to be limiting of the disclosure. Spatially relative terms, such as “beneath”, “below”, “lower”, “above”, “upper”, and the like may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (e.g., rotated 90 degrees or at other orientations) and the spatially relative descriptors used herein interpreted accordingly.

As used herein, the singular forms “a”, “an”, and “the” are intended to include the plural forms as well, unless the context indicates otherwise. It will be further understood that the terms “comprises” and/or “comprising” specify the presence of stated features, steps, operations, elements, and/or components, but do not preclude the presence or addition of one or more other features, steps, operations, elements, components, and/or groups thereof.

The terms “or” and “and/or” as used herein are to be interpreted as inclusive or meaning any one or any combination. Therefore, “A, B or C” or “A, B and/or C” mean “any of the following: A; B; C; A and B; A and C; B and C; A, B and C.” An exception to this definition will occur only when a combination of elements, functions, steps or acts are in some way inherently mutually exclusive.

While lids can provide mechanical integrity to an MCM, it has been observed that lids can also induce large stress and high warpage in an MCM and induce mechanical failures. For example, lids formed of copper may have a comparatively high coefficient of thermal expansion (CTE) relative to other module features. This can result in thermal expansion and induce stress and warpage in the MCM components (e.g., packages) when the lid is strongly coupled with the rest of the module. In accordance with embodiments, various lid structures are provided to balance the ability of the lid to provide mechanical integrity of the module while not inducing mechanical failure. For example, the lid may include what is referred to herein as an “island” or a “recessed island” configuration that can significantly mitigate TIM stress. In some aspects, the recessed island may include additional recessed regions (e.g., recessed corners) to further address TIM stress and delamination issues. The recess locations and areas can further be optimized based on a system-on-chip (SOC) die hot spot. The lid configuration may also enable a wider range of TIM material selection.

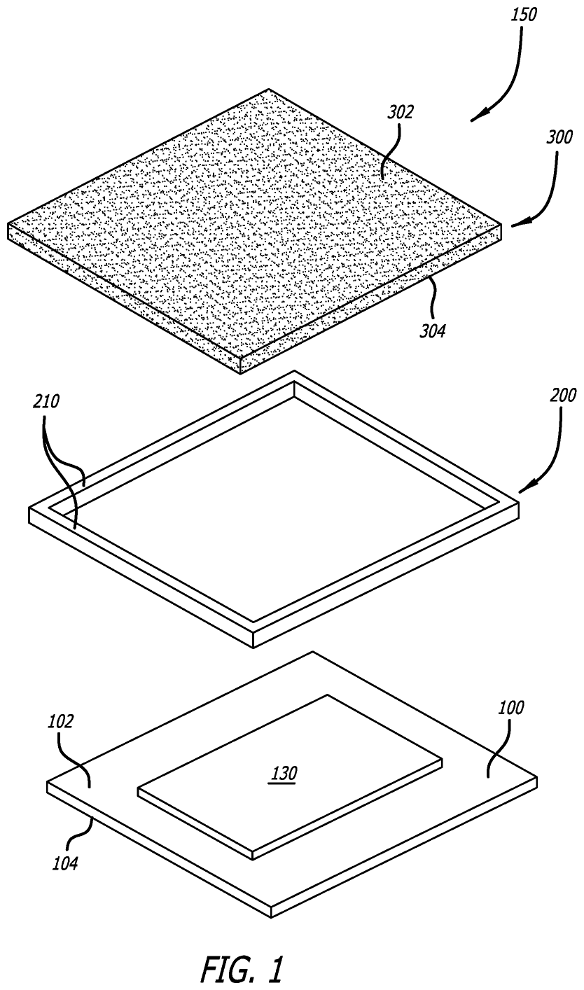

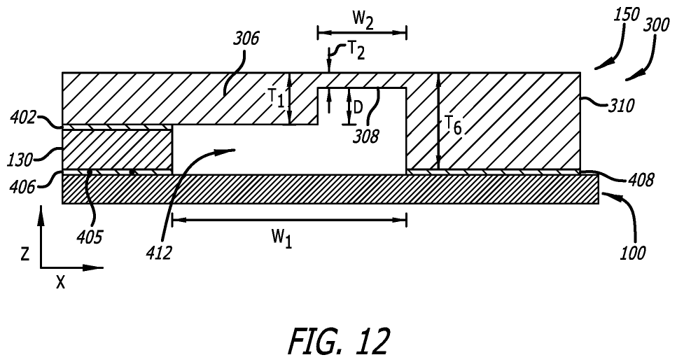

Referring now to FIG. 1 is an exploded isometric view illustration of a module 150 including a lid 300 and stiffener structure 200 with supports 210. In the exemplary embodiment, the module may be an MCM and therefore may be referred to interchangeably herein as a “module” or an “MCM”. MCM 150 includes a module substrate 100 including a top side 102 and bottom side 104. One or more components 130 can be mounted on the top side 102 of the module substrate 100. In some aspects, the one or more components 130 may include one or more of an SOC die and/or may include, or otherwise be paired with, a number of additional components of the electronic system, for example, active or passive devices including but not limited to memory packages (e.g., a dynamic random-access memory (DRAM)), a central processing unit (CPU), memory interfaces, input/output devices, and/or input/output interfaces. Component 130 may therefore also be referred to herein interchangeably as a die. Stiffener structure 200 may include supports 210 which are also mounted to top side 102 of substrate 100 and surround die 130. Supports 210 may form an overall ring like shape (e.g., around die 130) therefore in some aspects stiffener structure 200 may be referred to as a stiffener ring. Lid 300 may include a top side 302 and a bottom side 304 that covers or is mounted to support(s) 210 and/or die 130 as will be discussed in more detail in reference to FIG. 3. Lid 300 may, in some aspects, be a single integrally formed structure or unit formed from or by, for example, a metal material (e.g., copper). In other words, lid 300 is formed of a single piece of material and any lid portions or features disclosed herein are therefore also part of the same inseparable lid structure. In addition, it is further contemplated that in some aspects, stiffener structure 200 may be omitted and a similar stiffener structure may instead be integrated into lid 300 such that lid 300 is a one piece lid and stiffener structure as will be discussed in more detail in reference to FIG. 12.

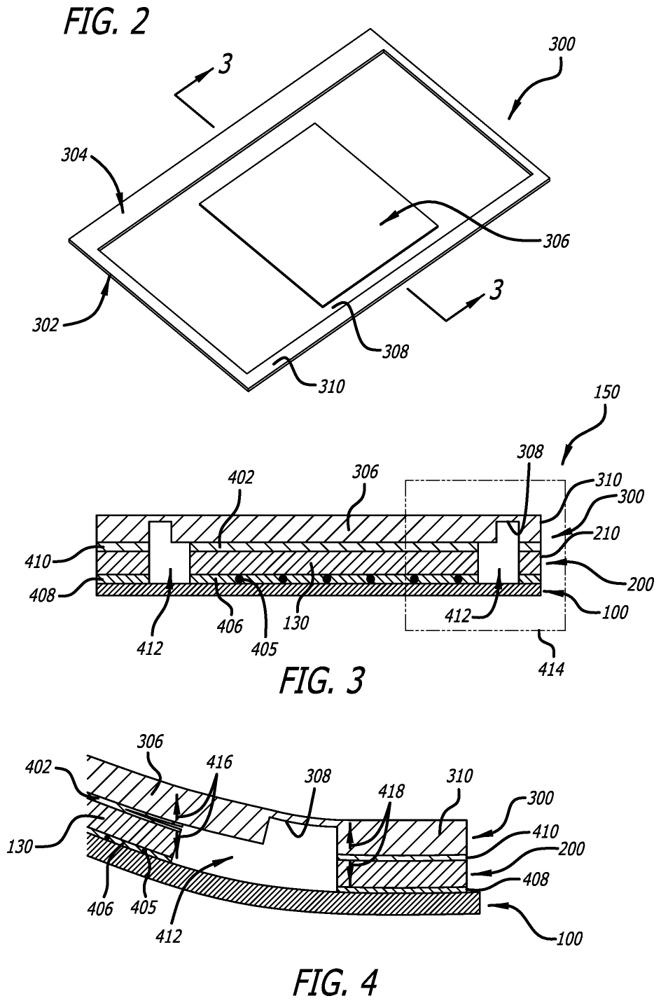

Referring now to FIG. 2, FIG. 2 illustrates a bottom perspective view of a representative lid from FIG. 1. Representatively, from this view, it can be seen that bottom side 304 of lid 300 includes a first portion 306 that is separated from a second portion 310 by a recessed region 308. Recessed region 308 may be understood as a cutout region within bottom side 304 of lid 300 that thins out lid 300 within that region, or results in region 308 of lid 300 being thinner (e.g., along a z-axis between top side 302 and bottom side 304) than the rest of lid 300. For example, recessed region 308 may be thinner than first portion 306 and second portion 308. In some aspects, recessed region 308 may entirely surround first portion 306 such that first portion 306 may resemble, or otherwise be referred to herein, as an island or recessed island. Second portion 310 may be formed around, and separated from, first portion 306 by recessed region 308. In still further aspects, first portion 306 may be generally positioned at a center of lid 300, or close to center, such that first portion 306 covers and/or is aligned with die 130 once assembled. First portion 306 may further have a similar shape and/or size to that of die 130, for example, a polygon-like shape such as a square or rectangle. In some aspects, the arrangement of first portion 306, second portion 310 and recessed region 308 about lid 300 may be symmetrical about a center axis (e.g., line 3-3′) of lid 300. It should be understood, however, that although a polygon-like shaped first portion 306 is illustrated in FIG. 2, other shapes and sizes of first portion 306 suitable for covering die 130 are contemplated.

Referring now to FIG. 3, FIG. 3 illustrates a schematic cross-sectional side view of the lid and stiffener structure of FIG. 1 (along line 3-3 of FIG. 2) assembled, in accordance with embodiments. From this view, it can be seen that die 130 is mounted onto the top side of module substrate 100. For example, in some aspects, die 130 may be mounted onto the top side of module substrate 100 using any suitable technique such as solder bumps 405, with an optional underfill 406 (e.g., epoxy).

Stiffener structure 200 is further shown mounted onto the top side of module substrate 100. For example, in some aspects, a bottom side of supports 210 may be positioned on the top side of substrate 100 around die 130 and bonded to substrate 100 using an adhesive material layer 408. For example, an adhesive can be dispensed onto the module substrate 100 at connection areas, followed by mounting the stiffener structure 200. Exemplary adhesive materials include glass paste, epoxies, urethane, polyurethane, silicone elastomers, etc.

Lid 300 is further shown bonded to die 130 and stiffener structure 200. Lid 300 may be bonded to stiffener structure 200 after mounting the stiffener structure on the module substrate 100, or before. Representatively, in some aspects, TIM layer 402 may be applied to the top side of die 130 to bond or otherwise secure the bottom side of lid 300 to die 130. In addition, a further adhesive layer 410 may be applied to the top side of supports 210 to bond or otherwise secure lid 300 to stiffener structure 200. TIM 402 may be applied using any suitable technique such as dispensing or a tape. Exemplary TIM 402 materials include those having both heat transfer and adhesive properties including, but not limited to, thermal grease, solder, metal filled polymer matrix, epoxy or silicone based formulation containing fillers, etc. Adhesive layer 410 may be of a same or different material than the previously discussed adhesive materials. It can further be seen from this view that first portion 306 of lid 300 is aligned with, and bonded to, die 130 while second portion 310 is aligned with, and bonded to, supports 210. Recessed region 308 is, in turn, aligned with the gap or space 412 between die 130 and stiffener structure 200. Recessed region 308 is therefore considered to define or be an open space or gap between first portion 306 and second portion 310 which is not occupied by (or directly attached to) any other structure (e.g., die 130 or stiffener structure 200).

It has been observed that regions where TIM or adhesive bonds lid 300 to die 130 or stiffener structure 200 can be a high stress location subject to delamination. Representatively, FIG. 4 is a magnified view of the region 414 of FIG. 3 illustrating TIM and adhesive stress at these regions. In particular, the region of TIM stress is illustrated by arrows 416 and the region of adhesive stress is illustrated by arrows 418. As can be understood by the arrows 416 and 418, these regions may experience stresses due to opposing forces (e.g., due to different CTE) and therefore tend to be more susceptible to delamination. These stresses, however, can be significantly mitigated by formation of the first portion 306 and second portion 310 separated by recessed region 308 in the bottom side of lid 300 as shown. In addition, the location and area of the recessed region 308 (and in turn first and second portions 306, 310) can be optimized based on the SOC die hot spot to further mitigate TIM delamination issues.

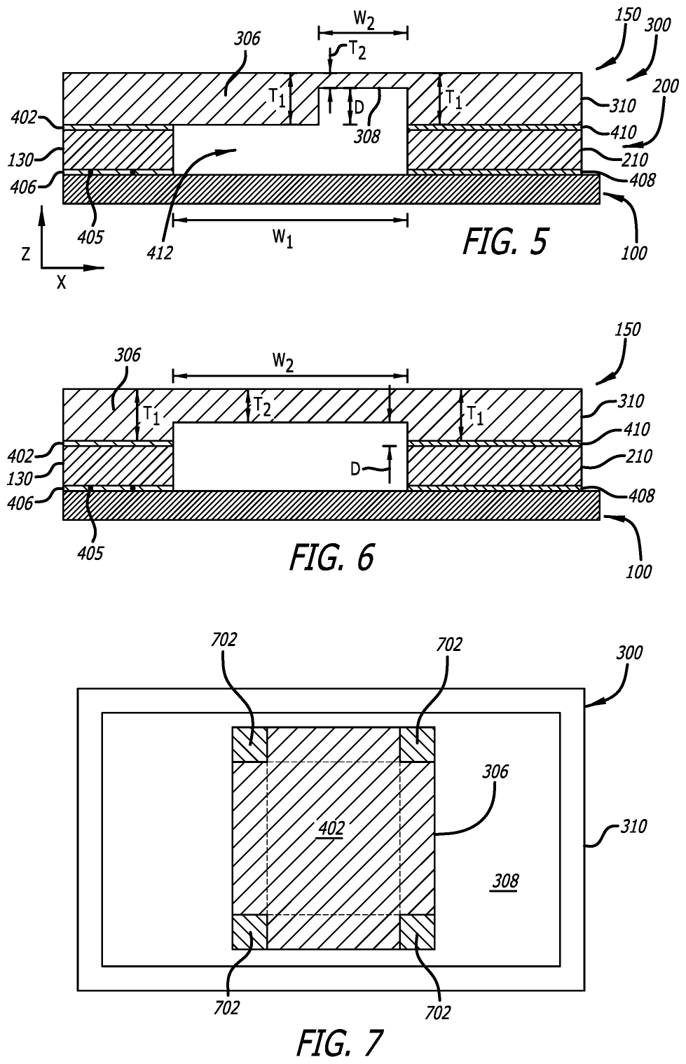

Representatively, FIG. 5 illustrates a further magnified view of region 414 of FIG. 3 in which the lid configuration is optimized to mitigate TIM delamination. In particular, from this view, it can be seen that space or gap 412 between die 130 and support 210 of stiffener structure 200 may have a first width (W1), as measured along the x-axis. The width (W1) between die 130 and support 210 is generally considered a fixed width or distance required or otherwise determined based on package design. Recessed region 308 may further be defined by a width (W2), as measured along the x-axis. The width (W2) of recessed region 308 may be optimized relative to the width (W2) between die 130 and support 210 to mitigate delamination. Representatively, it has been found that when W2/W1 is within a particular range, the recessed island configuration of lid 300 may be optimized to mitigate or improve TIM stress and/or adhesive stresses that result in delamination. For example, in some aspects, W2/W1 may be greater than zero but less than one. Said another way, W2 is preferably greater than zero and equal to or less than W1. In this aspect, W2/W1 may preferably be within a range of from about 0.5 to about 1, for example, from about 0.2 to about 0.8, or from about 0.3 to about 0.7, or from about 0.5 to about 0.6. For example, FIG. 5 may be considered to illustrate an embodiment in which W2 is less than W1 therefore W2/W1 is optimized within a range of between about 0.5 to about 0.6. Therefore, in this configuration, a size or area of first region 306 is relatively large and extends beyond that of die 130 as shown. On the other hand, FIG. 6 illustrates a further configuration in which W2 is increased to be equal to W1, therefore W2/W1 is 1. Therefore, in this configuration, while the width (W2) of recessed region 308 is increased, a size or area of first region 306 is reduced and may be closer to that of die 130 as shown.

As further illustrated by FIGS. 5-6, recessed region 308 also has a depth (D) that may be optimized to mitigate delamination as previously discussed. Representatively, first portion 306 and/or second portion 310 may be understood as having a thickness (T1) as measured along the z-axis. A portion of this lid thickness (T1) may be removed to form recessed region 308 having a depth (D) as shown and measured along the z-axis. In this aspect, the portion of lid 300 defining recessed region 308 between first portion 306 and second portion 310 may have a reduced thickness (T2) relative to the thickness (T1) of first and second portions 306, 310. The depth (D) may be optimized or tuned relative to the overall thickness (T1) of lid first and/or second portions 306, 310 to mitigate TIM/adhesive stress and delamination as previously discussed.

Representatively, it has been found that when D/T1 is within a particular range, TIM stress and/or adhesive stresses that result in delamination may be mitigated or otherwise improved. For example, in some aspects, D/T1 may be greater than zero but less than one. Said another way, D is preferably greater than zero and less than T1. In this aspect, D/T1 may preferably be within a range of from about 0.1 to about 0.9, for example, from about 0.2 to about 0.8, or from about 0.3 to about 0.7, or from about 0.5 to about 0.6. For example, FIG. 5 may be considered to illustrate an embodiment in which D is less than T1, therefore D/T1 is closer to 1, for example, from about 0.7 to about 0.9. Therefore, in this configuration, a thickness (T2) of lid 300 at recessed region 308 is minimized and less than that of first portion 306 and second portion 310. The depth (D) on the other hand is optimized to form a relatively deep recessed region 308. Therefore, in the configuration shown in FIG. 5, D/T1 is closer to one. On the other hand, FIG. 6 illustrates a further configuration in which depth (D) is reduced and thickness (T2) is increased relative to lid thickness (T1), therefore D/T1 is closer to zero. In some aspects, a ratio of D/T1 closer to 1 may be preferred.

In still further aspects, a combination of TIM materials may be used in addition to the island lid configuration to mitigate delamination issues. Representatively, FIG. 7 illustrates a bottom plan view of lid 300 previously discussed in reference to FIGS. 1-6. In this configuration, however, different TIM materials are applied to different regions of lid 300 depending on the stress at those regions making them susceptible to delamination. For example, in some aspects, TIM 402 as previously discussed may be applied to most, or a substantial portion, of first portion 306 covering die 130 and TIM 702 may be applied to the corners of first portion 306. TIM 402 may, for example, be a TIM having good thermal conductivity and suitable for bonding to the underlying die 130. TIM 702, on the other hand, may be a TIM that will more strongly bond lid 300 to die 130 but has relatively poor thermal conductivity. The stronger TIM 702 is therefore suitable for application at the corners where stresses may be higher and therefore delamination more of an issue, but not preferred over the bulk of first portion 306 that covers die 130, and where better thermal conductivity is desired. This combination or hybrid pattern of TIM 402 and 702, in combination with the island lid configuration, may further be used to help mitigate delamination issues. It should further be understood that although a pattern in which TIM 702 is localized to the corners of first portion 306 and TIM 402 covers the remainder of first portion 306, different hybrid TIM patterns are contemplated. For example, TIM 702 could be along the sides of first portion 306 as illustrated by the dashed lines, or other regions of first portion 306, susceptible to increased stress and delamination when bonded to the underling die 130.

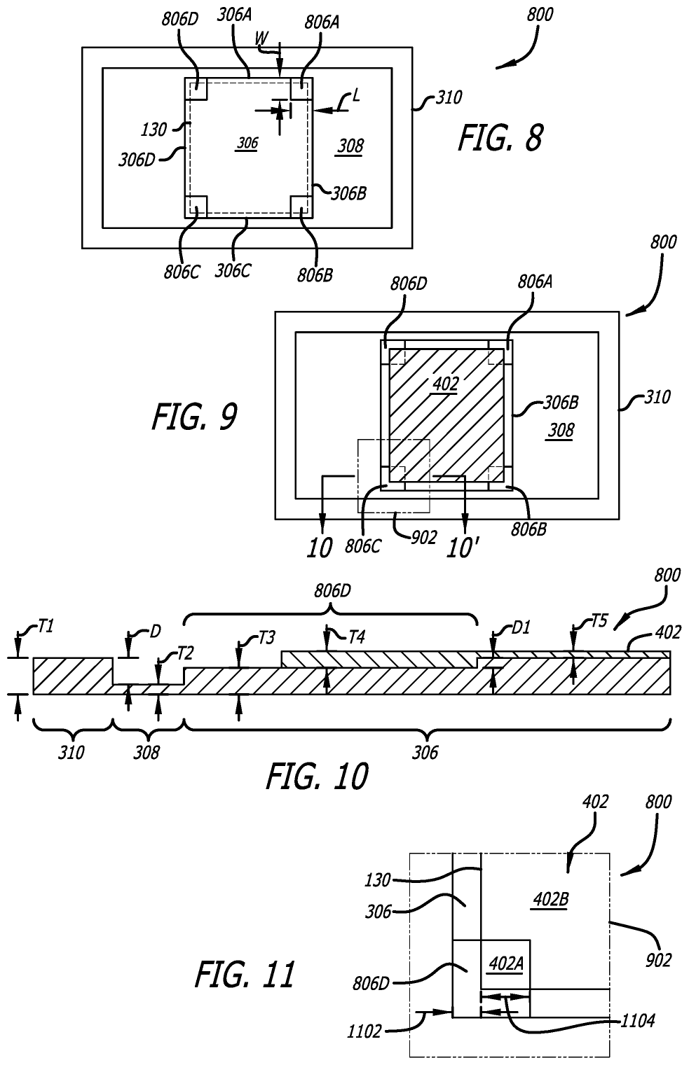

Referring now to FIG. 8-FIG. 11, FIG. 8-FIG. 11 illustrate a lid similar to previously discussed lid 300 that can be assembled with stiffener structure 200 and substrate 100 to form MCM 150, as previously discussed. Stiffener structure 200 and substrate 100, however, are omitted from FIGS. 8-11 for simplicity. In this aspect, FIG. 8 illustrates a bottom plan view of lid 800. Similar to the previously discussed lid 300, lid 800 may include first portion 306 separated from second portion 310 by recessed region 308. From this view, it can also be seen that recessed region 308 entirely surrounds first portion 306 such that first portion 306 is an island like structure and may be referred to herein as such. In addition, first portion 306 may have a polygon like shape. For example, first portion 306 may have a relatively square shape formed by four sides 306A, 306B, 306C and 306D that connect to form four corners. In addition, in this configuration, recessed regions may also be formed in one or more of the corners. Representatively, recessed regions 806A. 806B, 806C and 806D may be formed in the corners defined by sides 306A-D. In some aspects, recessed regions 806A-D may have a polygon like shape defined by a length (L) and width (W). The length (L) and width (W) may be less than that of sides 806A-D such that recessed regions 806A-D are relatively confined to the corners of first portion 306. For example, length (L) and width (W) may be less than sides 306A-D and substantially the same such that recessed regions 806A-D have a square shape. Alternatively, length (L) and width (W) may be different such that recessed regions 806A-D have a rectangular shape. In still further aspects, length (L) or width (W) could be the same as one or more of sides 306A-D such that recessed regions 806A-D extend along an entire side 806A-D of first portion 306. In addition, it is further contemplated that in other configurations, recessed regions may have other shapes and sizes, for example, may have triangular, rounded, circular or other shapes. Recessed regions 806A-D may therefore have different shapes and sizes, but should be of a shape and size such that recessed regions 806A-D along with TIM applied to this region overlaps the underlying die 130 illustrated by the dashed line.

Representatively, FIG. 9 illustrates a further bottom plan view of lid 800 having recessed regions 806A-D formed in corners of first portion 306 and TIM layer 402 applied to first portion 306. From this view, it can be seen that TIM layer 402 overlaps corner recessed regions 806A-D. TIM layer 402 may substantially conform to the bottom surface of lid 300 formed by first portion 306 and recessed regions 806A-D. Accordingly, TIM layer 402 within recessed regions 806A-D may be thicker than the TIM layer 402 over the rest of first portion 306. Having a thicker TIM layer 402 in the corners of first portion 306 will, in turn, help to reduce stress and mitigate delamination that may occur in these regions, similar to that discussed in reference to FIG. 7, but with a single TIM material.

Representatively, FIG. 10 illustrates a cross-sectional side view of a region of lid defined by dashed line 902 of FIG. 9 along line 10-10′. From this view, it can be seen that corner recessed region 806D is formed by further removing a portion of the material along the bottom side of first portion 306. This, in turn, forms corner recessed region 806D within first portion 306, which is next to recessed region 308 that surrounds first portion 302. Corner recessed region 806D may therefore further have a depth (D1). The depth (D1) of corner recessed region 806D within first portion 302 should be less than the depth (D) of recessed region 308 surrounding first portion 302 so that the island like structure of first portion 302 within lid 800 is maintained. Said another way, a thickness (T3) of corner recessed region 806D formed by first portion 306, should be greater than the thickness (T2) of the lid portion defining recessed region 308 but less than the overall thickness (T1) of first and second portions 306, 310. Due to the stepped like structure formed by corner recessed region 806D in first portion 306, a thickness (T4) of TIM layer 402 in the corner recessed region 806D is greater than a thickness (T5) along a remainder of first portion 306. This increased thickness (T4) of TIM layer 402 in the corners of first portion 306 increases the material strength in these regions and allows for the use of a single high-K TIM material. For example, in some aspects, the high-K TIM material may be a TIM material having a thermal conductivity higher than most other TIM materials, for example, a thermal conductivity up to about 7. Representatively, as previously discussed, a high-K TIM material between lid 800 and die 130 may be desired due to its high thermal conductivity but it may not be as strong as desired to mitigate delamination issues in high stress areas. Increasing the thickness of the high-K TIM material in these corner regions, however, alleviates this issue. Thus, TIM layer 402 may be formed by a single high-K TIM material while still having the desired reinforcement in the high stress corner regions to help mitigate delamination issues.

In addition, as further illustrated by FIG. 11, to maximize the TIM strength near the corners of the underlying die 130, TIM layer 402 may extend into corner recessed region 806D of first portion 306 of lid 800 such that it entirely overlaps the corner of the underlying die 130. Representatively, FIG. 11 is a bottom plan view of the region of lid defined by dashed line 902 of FIG. 9. From this view, it can be seen that first portion 306 is larger than the underling die 130 such that there is a distance or space 1102 between the edge of die 130 and the edge of first portion 306. Accordingly, TIM layer 402 may extend into the corner recessed region 806D such that it covers or overlaps die 130, but does not need to completely fill corner recessed region 806D. For example, TIM layer 402 may extend into recessed corner region 806D a distance 1104 such that it covers die 130 but does not occupy the space 1102 between edge of die 130 and edge of first portion 306. In this aspect, TIM layer 402 may form a thickened corner region 402A over a portion of the corner recessed region 806D of lid first portion 306 that is over the corner of the underlying die 130 and a thinner main region 402B that covers the remainder of the die 130. In this aspect, a single high-K TIM material may be used between lid 800 and die 130 while still helping to mitigate the previously discussed stress and delamination issues.

Referring now to FIG. 12, FIG. 12 is a magnified schematic cross-sectional side view illustration of an alternative lid structure in accordance with an embodiment. Similar to the previous configurations, it can be seen that die 130 is mounted onto the top side of module substrate 100. For example, in some aspects, die 130 may be mounted onto the top side of module substrate 100 using any suitable technique such as solder bumps 405, with an optional underfill 406 (e.g., epoxy). In this configuration, however, the previously discussed stiffener structure 200 is omitted and instead is formed as part of the lid 300. Representatively, lid 300 includes a first portion 306 and a surrounding recessed region 308 having a depth (D) and width (W2) tuned relative to the thickness (T1) and width (W1) so that first portion 306 has the desired configuration, as previously discussed. First portion 306 may be bonded to die 130 using TIM layer 402. In this configuration, however, the second portion 310 of lid 300 that surrounds the recessed region 308 has an increased thickness (T6) (e.g., greater than first portion thickness (T1)) such that second portion 310 extends all the way to substrate 100. Second portion 310 may then be attached to substrate 100 by adhesive 408. Second portion 310 of lid 300 therefore also serves as the stiffener surrounding die 130 as previously discussed. A separate stiffener structure (e.g., stiffener 200) is omitted. In this aspect, lid 300 may be considered a one-piece lid that accomplishes the functions of both a lid and stiffener structure of module 150.

In utilizing the various aspects of the embodiments, it would become apparent to one skilled in the art that combinations or variations of the above embodiments are possible for integrating an MCM lid structure while mitigating module warpage. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration. Thus, the description is to be regarded as illustrative instead of limiting. In addition, to aid the Patent Office and any readers of any patent issued on this application in interpreting the claims appended hereto, applicants wish to note that they do not intend any of the appended claims or claim elements to invoke 35 U.S.C. 112 (f) unless the words “means for” or “step for” are explicitly used in the particular claim.

What is claimed is:

1. A module comprising:
a module substrate;
a system-on-chip die coupled to the module substrate;
a thermal interface material layer coupled to the system-on-chip die;
a stiffener structure positioned around the system-on-chip die and coupled to the module substrate; and
a lid having a first portion coupled to the thermal interface material layer, a second portion coupled to the stiffener structure and a recessed region formed around the first portion and having a reduced thickness relative to the first portion and the second portion.

2. The module of claim 1 wherein the lid is a single integrally formed structure.

3. The module of claim 1 wherein the recessed region is formed entirely around the first portion.

4. The module of claim 1 wherein the recessed region is aligned with a gap between the system-on-chip die and the stiffener structure.

5. The module of claim 1 wherein a gap between the system-on-chip die and the stiffener structure comprises a first width (W1) and the recessed region comprises a second width (W2) that is greater than zero and equal to or less than the first width (W1).

6. The module of claim 1 wherein the recessed region comprises a depth (D) that is greater than zero and less than a thickness (T) of the first portion and the second portion of the lid.

7. The module of claim 1 wherein the first portion comprises a polygonal shape.

8. The module of claim 7 wherein the thermal interface material layer comprises a first thermal interface material arranged along a center of the first portion and a second thermal interface material arranged along a corner of the first portion.

9. The module of claim 1 wherein the recessed region is a first recessed region and a second recessed region is formed in at least one corner or along at least one side of the first portion.

10. The module of claim 9 wherein the thermal interface material layer comprises a single thermal interface material having a first thickness and a second thickness, the second thickness is formed in the second recessed region and is greater than the first thickness.

11. A module comprising:
a module substrate;
a system-on-chip die coupled to the module substrate;
a thermal interface material layer coupled to the system-on-chip die;
a stiffener structure positioned around the system-on-chip die and coupled to the module substrate; and
a lid having a bottom side comprising a first portion coupled to the thermal interface material layer and a recessed region formed entirely around the first portion that is aligned with a gap between the system-on-chip die and the stiffener structure.

12. The module of claim 11 wherein the lid is a single inseparable structure formed of a metal material.

13. The module of claim 11 wherein the recessed region is formed entirely around the first portion.

14. The module of claim 11 wherein the gap between the system-on-chip die and the stiffener structure comprises a first width (W1) and the recessed region comprises a second width (W2) that is greater than zero and equal to or less than the first width (W1).

15. The module of claim 11 wherein the recessed region comprises a depth (D) that is greater than zero and less than a thickness (T) of the lid.

16. The module of claim 11 wherein the first portion comprises a rectangular or a square shape.

17. The module of claim 16 wherein the thermal interface material layer comprises a first thermal interface material and a second thermal interface material having a different thermal conductivity than the first thermal interface material, and the first or the second thermal interface material is confined to at least one corner of the first portion.

18. The module of claim 11 wherein the recessed region is a first recessed region and a second recessed region is formed in each corner of the first portion.

19. The module of claim 18 wherein the thermal interface material layer comprises a single thermal interface material having a greater thickness within the second recessed region formed in each corner of the first portion than a remainder of the first portion.

20. The module of claim 11 wherein the stiffener structure is an integrally formed part of the lid and surrounds the recessed region.
